(19) United States
(12) Patent Application Publication
(10) Pub. No.: US 2024/0060634 A1
(43) Pub. Date: Feb. 22, 2024

(54) Heat sink as well as associated devices and methods

(71) Applicant: Thermal Channel Technologies Oy, Oulu (FI)

(72) Inventors: Vesa Pentikäinen, Oulu (FI); Kimmo Jokelainen, Oulu (FI)

(21) Appl. No.: 18/260,783

(22) PCT Filed: Nov. 30, 2021
(86) PCT No.: PCT/FI2021/050829

§ 371 Date: Jul. 8, 2023

(30) Foreign Application Priority Data
Jan. 8, 2021 (FI) 20215018

(51) Int. Cl. F21V 29/75; F28F 1/16; F28D 1/047; F21V 7/04; F21V 29/56

(52) U.S. Cl. CPC F21V 29/75; F28F 1/16; F28D 1/047; F21V 7/041; F21V 29/56; F21Y 2115/10

(57) ABSTRACT

According to an example aspect of the present invention, there is provided a heat sink (100) with an elongated inner core (110) and an elongated outer profile (120). The profile (120) forms a cross-sectional periphery and is provided around and at a distance from the core (110) such that an intermediate volume (160) is formed between the core (110) and the profile (120). The heat sink (100) also has abridge (130) connecting the profile (120) to the core (110). The profile (120) has at least one opening (140) exposing the intermediate volume (160) to the ambient. The at least one opening (140) extends in a direction which is non-parallel to the dimension of elongation of the inner core (110).

### FIELD

The present disclosure relates to devices for cooling. In particular, the present disclosure relates to heat dissipating apparatuses.

### BACKGROUND

The cooling of electric components, such as microprocessors, LEDs, IGBT modules, etc., is conventionally based on attaching a heat transfer element to physical and thermally conducting connection to the component. Heat sinks have been traditionally made by, for example, die casting or extruding an elongated profile with several fins, kinks, and other shapes to maximize the surface area for dissipation. US 2009071624 A1 and EP 2193310 B1 disclose exemplary extruded heat sinks with longitudinally extending openings provided to the outer periphery.

Conventional heat sinks may be seen as suffering from certain drawbacks. If the heat sink is produced by die casting, the tooling is relatively expensive worsened by a limited life of the mold. In addition, the manipulation of the mold lengthens the process pace time and the regular materials used in die casting typically have only modest thermal conductivity, and the shaped produced may not allow for effective heat dissipative shapes. Extrusion, on the other hand, is a very effective method for producing large quantities of material. Heat sinks produced by extrusion may, however, suffer from limited freedom in design as the extruded shapes do not permit effective installation in non-vertical orientations.

The remains a need to provide for a cooling solution that is not only effective but susceptible for mass production with conventional manufacturing methods and tools.

### SUMMARY

The invention is defined by the features of the independent claims. Some specific embodiments are defined in the dependent claims.

According to a first aspect of the present disclosure, there is provided a heat sink with an elongated inner core and an elongated outer profile. The profile forms a cross-sectional periphery and is provided around and at a distance from the core such that an intermediate volume is formed between the core and the profile. The heat sink also has a bridge connecting the profile to the core. The profile has at least one opening exposing the intermediate volume to the ambient. The at least one opening extends in a direction which is non-parallel to the dimension of elongation of the inner core. In other words, the extension lies in a direction which has a component along the cross-sectional periphery of the profile.

According to a second aspect of the present disclosure, there is provided a heat dissipating system having a plurality of such heat sinks and a coupler with a plurality of channels for receiving the cores of the plurality of heat sinks.

According to a third aspect of the present disclosure, there is provided an illuminator having such a heat sink and an artificial light source mounted on a coupler for connecting the light source to the heat sink.

According to a fourth aspect of the present disclosure, there is provided an illuminating system having a plurality of such illuminators each comprising artificial light source and a plurality of such heat sinks. The coupler features a plurality of channels for receiving the cores of the plurality of heat sinks and the plurality of artificial light sources are mounted on the shared coupler.

According to a fifth aspect of the present disclosure, there is provided a method for producing a heat sink comprising providing a pre-form with an additive manufacturing technique to include an inner core, an outer profile, which forms a periphery and is provided around and at a distance from the core such that an intermediate volume is formed between the core and the profile, and a bridge connecting the profile to the core. In the method at least one opening is provided to the profile with a material removing manufacturing technique such that the at least one opening extends in a direction which has a component along the periphery of the profile and exposes the intermediate volume to the ambient.

According to a sixth aspect of the present disclosure, there is provided a method of installing a heat source mounted on such a heat sink to a receptive structure, wherein the elongated heat sink is installed in a non-horizontal tilted angle in respect to the vertical with the heat source facing down.

According to a seventh aspect of the present disclosure there is provided a heat exchanger comprising a first and second such heat sink, both of which comprise a hollow core, and a coupler, which connects the hollow cores the heat sinks into a flowing connection with one another.

Some embodiments may include one or more features from the following itemized list:
the at least one opening extends along the periphery of the profile;
the at least one opening extends around the entire periphery of the profile splitting the profile into several profile sections;
the profile is elongated in a dimension of elongation;
the dimension of elongation is a straight axis of elongation;
the dimension of elongation is the linear axis of extrusion of the heat sink work piece;
the profile comprises a plurality of said openings spaced apart from each other along the profile in the dimension of elongation of the profile;
the core is elongated in a dimension of elongation;
the openings are provided radially in respect to and rotationally about the dimension of elongation of the core;
the at least one opening extends through the bridge exposing the core to the ambient;
the core is hollow;
the core comprises a heat pipe integrated into the core;
the bridge comprises a plurality of spokes extending between the core and the profile through the intermediate volume;
at least one spoke comprises a plurality fins extending from the at least one spoke;
an initial extending angle of more than 90 degrees is formed between the spoke and the fin on the profile side of the fin the tangent of the fin changes as a function of distance from the spoke increasing the angle formed between the spoke and the tangent of the fin on the profile side of the fin;
at least one spoke comprises a socket;
the socket is provided with a female thread for acting as a mounting point;
the heat sink comprises a coupler for receiving a heat source;
the coupler comprises a channel for receiving the core;
the coupler comprises a vapour chamber in fluid communication with the channel;
the cross-section of the vapour chamber is larger than that of the channel;
the parts making up the heat sink are integral to one another;
the additive manufacturing technique is extrusion;
the material removing manufacturing technique is a chip removing manufacturing technique;
the material removing manufacturing technique is lathing,
the intermediate volume is annular.

Considerable benefits may be gained with aid of the present solution. The proposed shape can be produced by conventional manufacturing techniques, such as extrusion and lathing, making the production very suitable for mass production in large volumes. Additionally, the open outer profile leads to a relatively free flowing air flow along the heat sink to facilitate heat dissipation. With the cross-sectional periphery of the profile opened at last partly along the periphery, ambient air may pass from the outside to the intermediate volume between the periphery and the core. The elongated shape of the heat sink combined with the relatively warm or hot core means that the cooling air flow is promoted along the core similarly to the chimney effect. The remaining part of the profile around the openings ensures that the air cannot easily escape from the intermediate volume through the profile but rather out the longitudinal end of the heat sink. By varying the size, distribution and location of the openings, one may optimize the flowing characteristics of the chimney effect. Additionally or alternatively, by varying the length of the heat sink along the dimension of elongation, the capacity of the heat sink may be tailored for a particular application. The cooling air flow improves the efficiency of the heat sink, whereby less material is required for dissipating an amount of heat previously requiring a relatively large heat sink.

On the other hand, it is preferable that the profile extends fully around the core at least partly along the dimension of elongation so as to sustain rigidity of the heat sink. If the openings extend through the bridge in addition to the profile, air may flow anywhere within the intermediate volume. Natural air flow is enabled also in tilted orientations which makes the heat sink suitable for many cooling applications. If the openings would not contain a component along the cross-sectional periphery of the profile, the air flow would not be very effective in cooling the structure, when installed in a tilted orientation.

According to one embodiment the heat sink includes an inner flow cavity inside the core. Heat transfer from the heat source to the opposing end of the heat sink is thereby greatly improved, whereby the entire heat dissipation capacity of the heat sink may be taken to full use.

### BRIEF DESCRIPTION OF THE DRAWINGS

In the following certain embodiments are described with reference to the accompanying drawings, in which:

FIG. 1 illustrates a perspective view of an illuminator provided with a heat sink in accordance with one embodiment;

FIG. 2 illustrates a perspective view of the illuminator according to modified version of FIG. 1 without the reflector and body of the illuminator and with a simplified heat sink;

FIG. 3 illustrates an exploded cross sectional view of the illuminator according to FIG. 2;

FIG. 4 illustrates a perspective view of a heat sink in accordance with another embodiment featuring a modified bridge with expanded fins;

FIG. 5 illustrates an axial elevation view of the heat sink according to FIG. 4;

FIG. 6 illustrates a perspective view of a heat sink in accordance with yet another embodiment featuring a modified bridge with curved fins;

FIG. 7 illustrates a perspective view of an illuminating system with a plurality of illuminators according to FIG. 2 mounted on a shared coupler;

FIG. 8 illustrates a cross-sectional view of the illuminating system according to FIG. 6;

FIG. 9 illustrates a perspective view of a heat exchanger with a plurality of heat sinks according to FIG. 2 mounted on a shared coupler;

FIG. 10 illustrates a cross-sectional view of the heat exchanger according to FIG. 8;

FIG. 11 illustrates a perspective view of flow through heat exchanger with a plurality of heat sinks according to FIG. 4 connected in series;

FIG. 12 illustrates a perspective view of the illuminator according to FIG. 2 provided with expander plates;

FIG. 13 illustrates a perspective view of the illuminating system according to FIG. 7 provided with expander plates;

FIG. 14 illustrates a perspective view of the illuminating system according to FIG. 7 provided with creased expander plates;

FIG. 15 illustrates a perspective view of the illuminating system according to FIG. 7 provided with folded expander plates;

FIG. 16 illustrates a perspective view of a heat sink in accordance with another embodiment featuring a modified profile shape;

FIG. 17 illustrates a perspective view of a heat sink in accordance with another embodiment featuring a modified orientation of the openings, and

FIG. 18 illustrates the principle of determining the direction of extension of an exemplary opening of the heat sink of FIG. 17.

### EMBODIMENTS

### Definitions

In the present context the expression “proximal end” refers to the end of the heat sink, which is proximal to the heat source. Conversely, the “distal end” refers to the end of the heat sink, which is distal to the heat source, i.e. the opposite end in respect to the proximal end.

In the present context the expression “dimension of elongation” may refer to the axis of greatest dimension. In case of straight profiles, the axis is linear. In case of bent profiles, the axis may be curved. According to an especially practical embodiment, the dimension of elongation is the linear axis of extrusion of the heat sink before the openings are introduced to the work piece.

In the present context “cross-sectional” views are to be understood, unless otherwise explained, as having been taken across the dimension of elongation of the component being discussed.

In the present context the word “periphery” should be understood to cover both continuous or broken peripheries. The periphery may be understood as a projection of the cross-sectional shape of the profile taken across the dimension of elongation of the profile cast on an imaginary plane.

In the present context the expressions “phase transition”, “phase change”, and “phase shift” are used interchangeably.

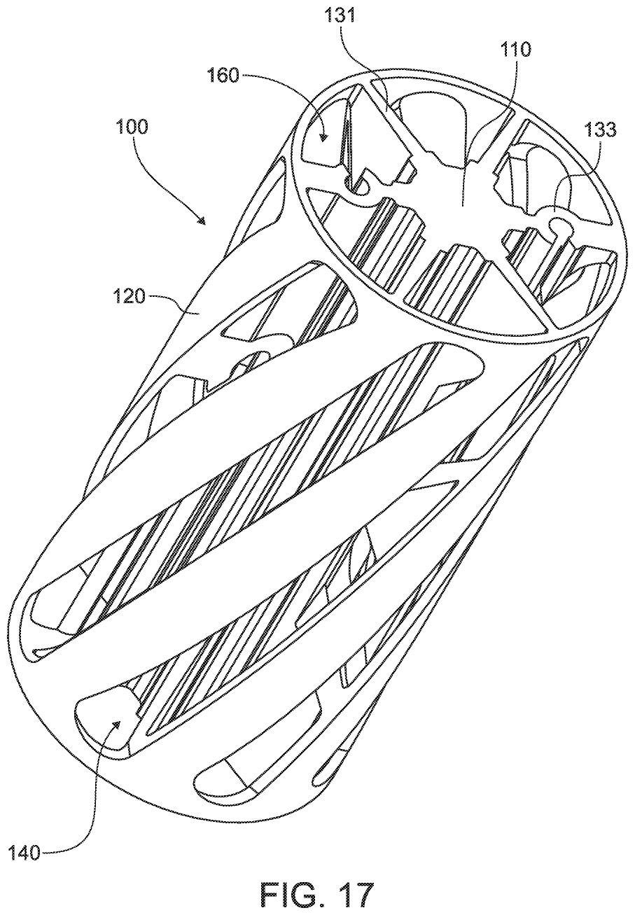

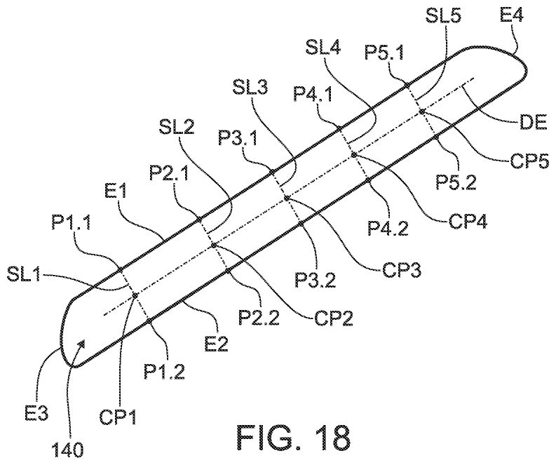

In the present context the direction in which an opening extends is defined by first finding the shortest distance between opposing edges, which define the opening, at a given point along the edge, then establishing the center point of the imaginary line segment connecting the edges at the shortest distance, repeating the same along the elongated opening, connecting the center points, whereby the resulting connecting line defines the direction of extension of the opening. FIG. 18 illustrates this principle with an opening 140 of FIG. 17. The exemplary opening 140 is delimited by two elongated and mutually opposing side edges E1, E2 and two curved and mutually opposing end edges E3, E4 which connect the side edges E1, E2 to each other. In the illustrated example five first reference points P1.1, P2.1, P3.1, P4.1, P5.1 were taken along a first elongated side edge E1 of the opening 140, whereby five corresponding points P1.2, P2.2, P3.2, P4.2, P5.2 were taken on the opposing second elongated side edge E2 at the shortest distance from the first reference points P1.1, P2.1, P3.1, P4.1, P5.1. The direction of extension DE is formed by connecting the center points CP1, CP2, CP3, CP4, CP5 of the segment lines SL1, SL2, SL3, SL4, SL5 that connect the first and second reference points P1.1, P1.2; P2.1, P2.2; P3.1, P3.2; P4.1, P4.2; P5.1, P5.2. While the illustrated example yields a straight direction of extension, it should be noted that the direction of extension may alternatively be curved or have another non-straight shape depending on the shape of the opening.

In the present context the expression “to extend in a direction” includes but is not limited to a meaning that the direction of extension is the direction, in which the opening has its greatest extension.

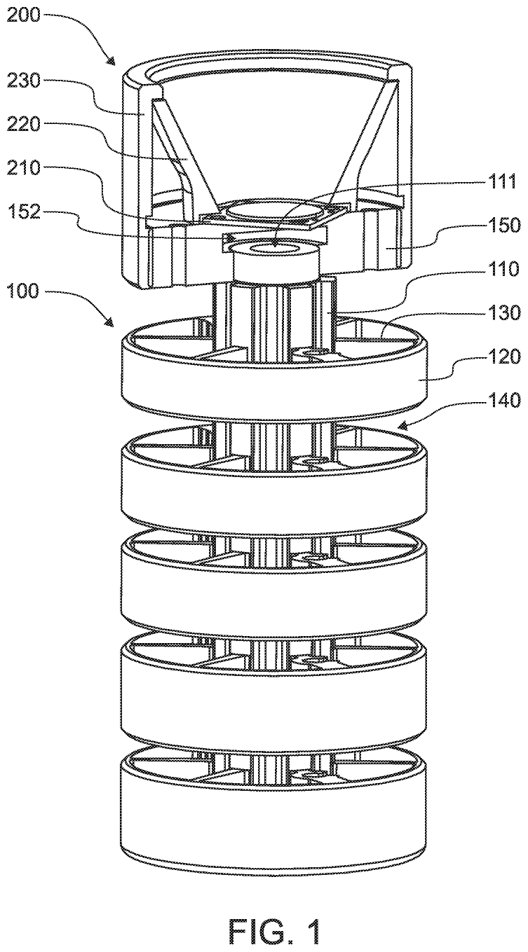

FIGS. 1 to 3 illustrate an illuminator cooled with a heat sink 100 in accordance with at least some embodiments. The apparatus of FIGS. 1 to 3 includes two major parts; heat source 200 and a heat sink 100. An illuminator is disclosed as an example of an applicable heat source but it could be replaced, for example, with another heat source, e.g. an IGBT module, a processor, a high power IC, a laser diode, a PCB or electronic module, an RF component, such as a radiator or a filter, or any other foreseeable electric or optical component that generates heat. The illuminator has a generally cylindrical body 230 which houses an LED chip 210 through a trunco-conical reflector 220. The illuminator may include further optics, such as a lens or objective, which have been omitted from the FIGURES for the sake of simplicity.

The LED chip 210 is mounted on a coupler 150 which connects the heat source 200 to the heat sink 100. In the present example the coupler 150 takes the form of a generally cylindrical piece which is shaped to connect to the heat source 200 on the one hand and to the heat sink 100 on the other hand. The body 230 of the illuminator may be attached to the similarly shaped body 230 of the heat source 200 by a shrink fit, threads, thermal fitting, brazing, welding, gluing or affixers. The outer cylindrical surface of the coupler 150 may, for example, comprise a male thread designed to fit a female thread on the body 230. The top surface of the coupler 150 may be flat to accommodate circuit board of the LED chip 210. The coupler 150 may also include through holes as feed-throughs for the wiring of the heat source 200.

The heat sink 100 has three major sections: a core 110, a profile 120 surrounding the core 110, and a bridge 130 connecting the core 110 to the profile 120 such that an intermediate volume 160 is formed there between. Let us first consider the core 110. The core 110 is elongated meaning that it has one dominant dimension of elongation. In the illustrated embodiment the dimension of elongation is straight but the core could alternatively be elongated along a curved dimension of elongation. The core 110 has a generally circular cross-section across the dimension of elongation making the core 110 generally cylindrical in shape. Alternatively, the outer cross-sectional shape of the core could be varied to an oval, triangular, quadrangular, hexagonal, or any suitable shape. The illustrated rotational symmetry is not a requirement.

The diameter of the core 110 is reduced at one end through a shoulder 112. The purpose of the reduction is to fit the core 110 into a receptive channel 151 provided to the coupler 150. Indeed, the coupler 150 includes an opening on the opposing side in respect to the heat source 200 for receiving the heat sink 100. More specifically, the bottom side of the coupler 150 includes a channel 151 for receiving the core 110.

The core 110 may be hollow to include a channel. The channel runs in the dimension of elongation. According to the illustrated example the channel extends through the core 110. Such extension is foreseeable if the core 110, and the rest of the heat sink 100 for that matter, is produced by extrusion. Alternatively, but the channel may alternatively be blind. Indeed, the core 110, profile 120, and bridge 130 may alternatively be extruded into a work piece, which is then machined to include the channel and openings. Whether made by extrusion or drilling, the core 110 may include more than one channel, wherein the channels may have the same or different size to one another.

To close the second end of the core 110 the channel may include a seat 113, which is an enlarged section compared the rest of the channel, and a plug 114 inserted into the seat 113. Naturally, the internal channel of the core 110 could be sealed with an alternative means, such as a plug conforming to the regular cross-section channel or a completely external lead which seals against the second end of the core 110. The channel of the core 110 may be used for facilitate heat transfer along the dimension of elongation from the end proximal to the heat source and the end distal to the heat source.

According to a foreseeable variant, the core may include a channel which runs through the core and which is plugged at both ends. The heat source may be mounted on either end or side of the core through the plug.

According to one embodiment the core 110 comprises a heat pipe 111. The heat pipe 111 may be integrated into the hollow core 110, e.g. by casting or extruding the core with the heat pipe as a unitary piece. Alternatively, the heat pipe may be added to the core by, e.g. a compression fit or by welding. The heat pipe 111 is closed. The heat pipe 111 may be closed at one end by the coupler 150 and at the other end by a plug 114. The heat pipe 111 comprises a phase transfer fluid. The phase transfer fluid is preferably used for performing a thermosiphon cycle within the heat pipe 111.

According to one embodiment the internal channel acts as a heat pipe 111. Once attached to the coupler 150, the heat pipe 111 of the core 110 is in fluid communication with the channel 151 of the coupler 151. The heat produced by the heat source 200 is then able to transfer to the distal end with aid of the heat pipe principle. The inner flow cavity produced by the channel 151 and the heat pipe 111 is therefore preferably closed and contains a phase transfer fluid to perform a thermosiphon cycle. To further promote heat transfer, the coupler 150 may include a vapour chamber 152 in fluid connection with the channel 151. The vapour chamber 152 may be an enlarged section of the channel 151 in proximity with the surface of the coupler 150 for receiving the heat source (LED chip 210 in FIGS. 1 to 3).

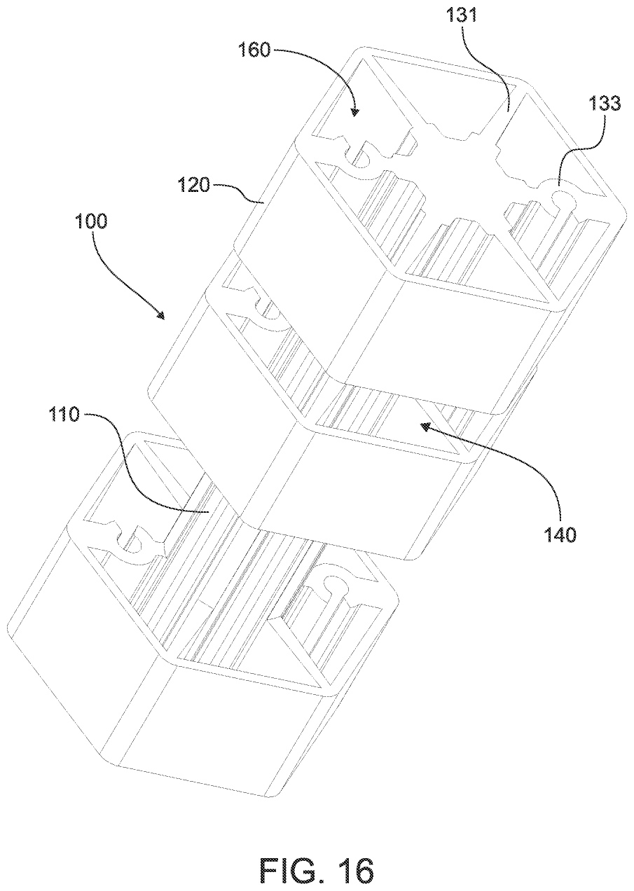

As mentioned above, an outer profile 120 surrounds the core 110 so as to create a broken and floating shell. The profile 120 shares a dimension of elongation with the core 110. Similarly to the core 110, the dimension of elongation may be curved. However, a straight orientation is preferred so as to enable manufacturing by extrusion. The profile 120 may have a circular cross-sectional shape when viewed across the dimension of elongation, or any foreseeable shape such as oval, triangular, quadrangular, or hexagonal, for example. FIG. 16 includes a variant of the heat sink of FIG. 1 with a generally hexagonal profile 120. The profile includes six faces connected by rounded corners. The heat sink 100 includes two openings, a short and a long one, dividing the profile 120 into three sections. An intermediate volume 160 is formed into the space between the core 110 and the profile 120. The intermediate volume 160 is annular in the example illustrated in FIGS. 1 to 15 and 17 and houses the bridge 130.

The outer profile 120 has been provided with at least one opening 140 for exposing the intermediate volume 160 to the environment. While one opening 140 may be sufficient for some applications of the present heat sink concept, the illustrated embodiment features four openings 141, 142, 143, 144 arranged in succession and in a spaced apart fashion on the profile 120 along the dimension of elongation thereof. The four openings 141-144 split the profile 120 into respective four profile sections 121, 122, 123, 124. The four exemplary openings 141, 142, 143, 144, which are from now on referred simply as the openings 140, extend at least in part along the periphery of the outer profile 120. The illustrated openings 140 are arranged to be run around the profile 120 along the periphery thus making the openings 140 not only radial but also rotational in respect to the dimension of elongation of the profile 120. Such a radial nature of the openings 140 renders the profile 120 as a ring around the core 110, whereby the ring may have a circular or otherwise shaped form when viewed in an elevation view along the dimension of elongation.

However, the openings 140 need not extend around the entire periphery of the profile 120 as shown in the FIGURES. Instead, the openings 140 may extend only for a section of the periphery (not shown in the FIGURES). Additionally or alternatively, the openings 140 may be elongated such that the dimension of elongation of the opening 140 has one component along the periphery of the cross-sectional shape of the profile 120 and another component along the dimension of elongation of the profile 120. In other words, the openings 140 may extend in a straight angle in respect to the dimension of elongation of the profile 120 or they may extend in a diagonal or slanted orientation in respect to the dimension of elongation of the profile 120. In the example illustrated in FIGS. 1 to 16, the dimension of elongation of the openings 140 have no component along the dimension of elongation of the profile 120. In the example illustrated in FIG. 17, the openings 160 extend in a direction which has a component both along the periphery of the profile 120 and along the dimension of extension of the profile 120, i.e. in the axial dimension of the profile 120, which happens to be straight. The openings 140 have a slightly spiral shape. It is preferable that the openings 140 do not extend along the entire dimension of elongation of the profile 120 so as to leave the ends of the profile 120 unbroken. This improves the rigidity of the piece. The slanted openings may only piece the profile 120, as is shown in FIG. 17, or they may extend through the bridge to the core. It may also be seen from FIGS. 1 to 3 that the openings 140 may extend to the core 110 of the heat sink 100 thus cutting through the bridge 130. Such a deep cut is optional. According to a non-illustrated embodiment, none or only a small section of the bridge 130 is affected by the openings 140.

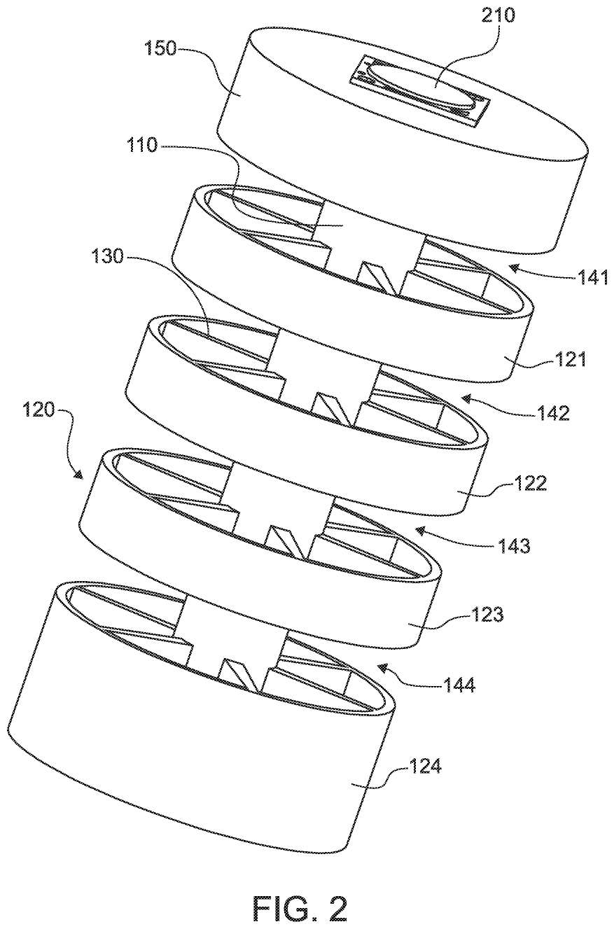

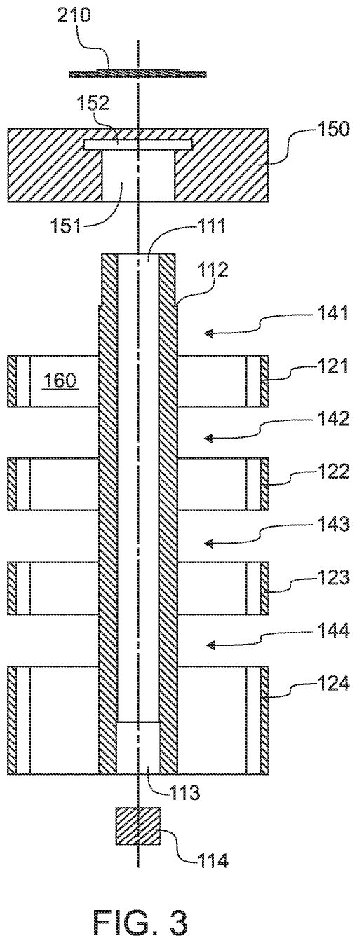

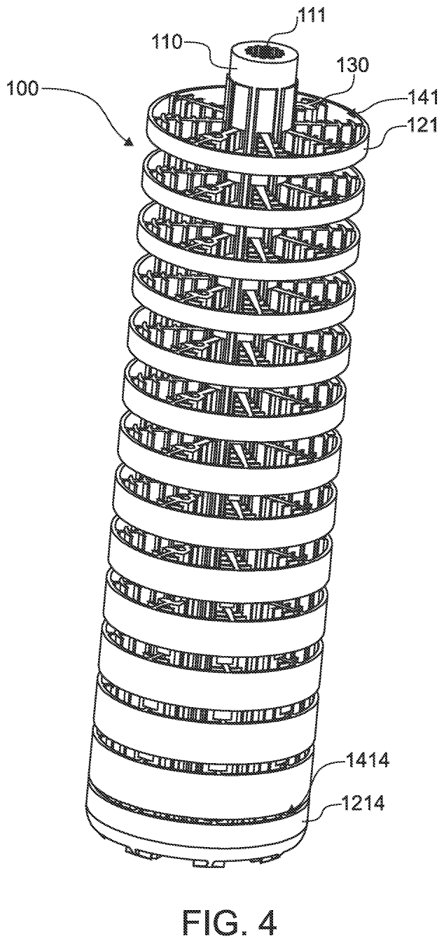

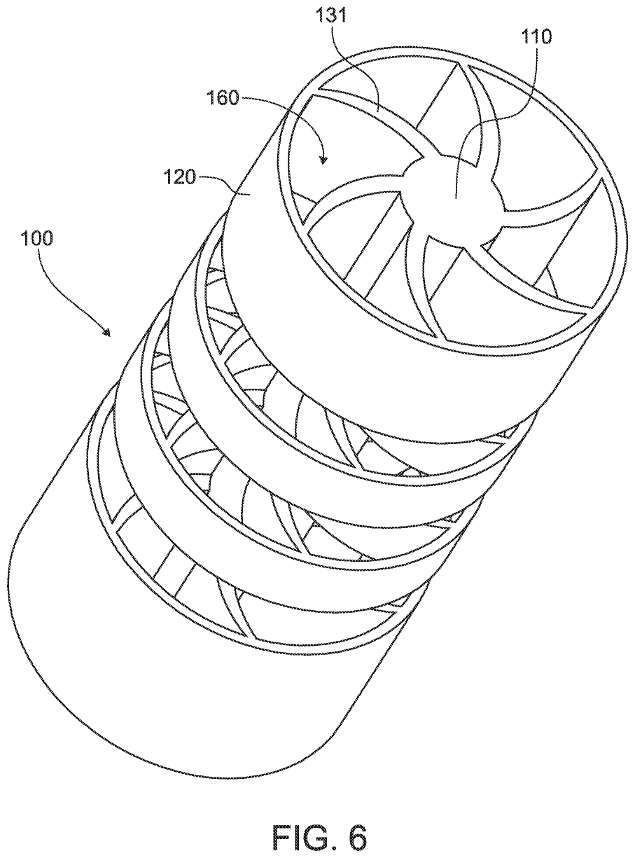

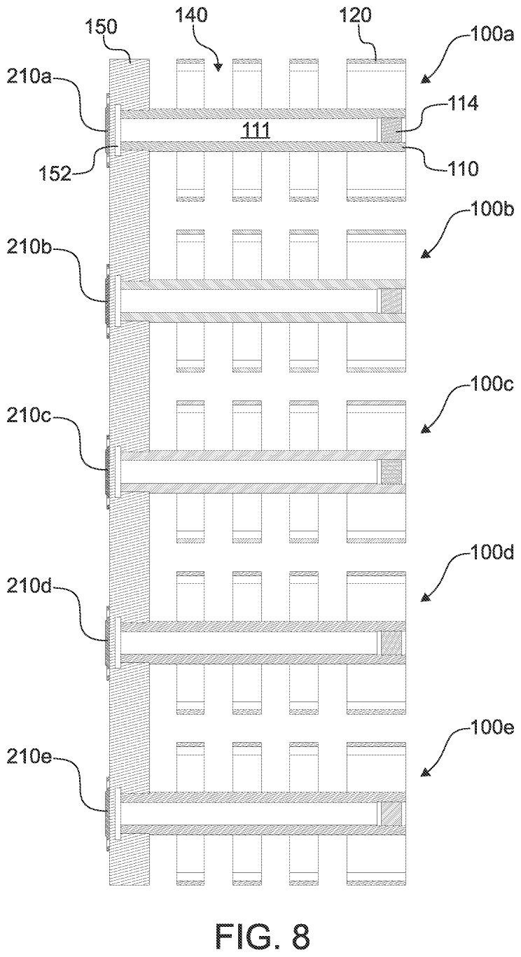

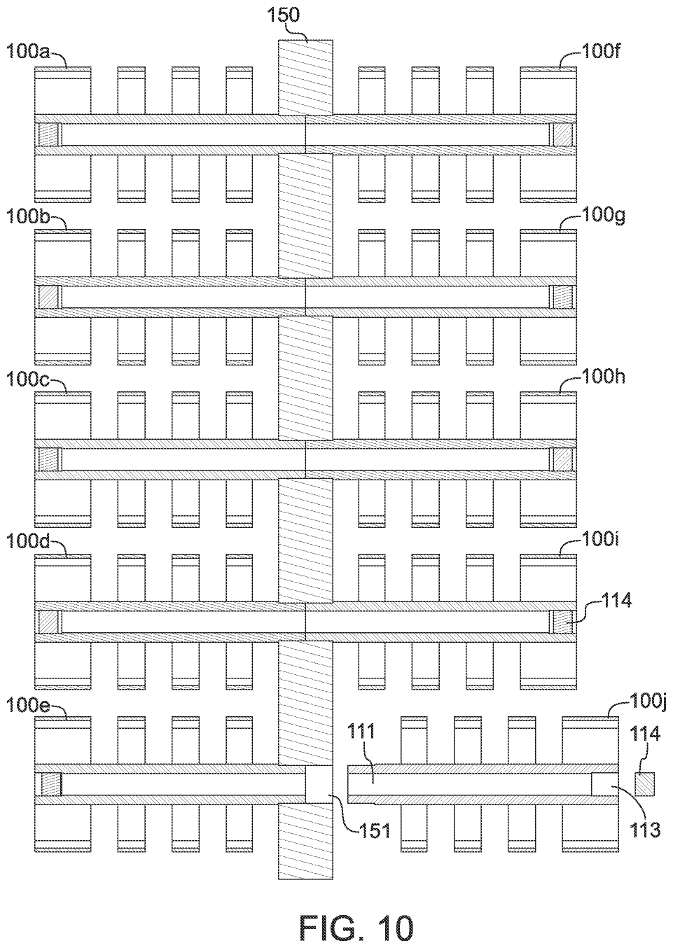

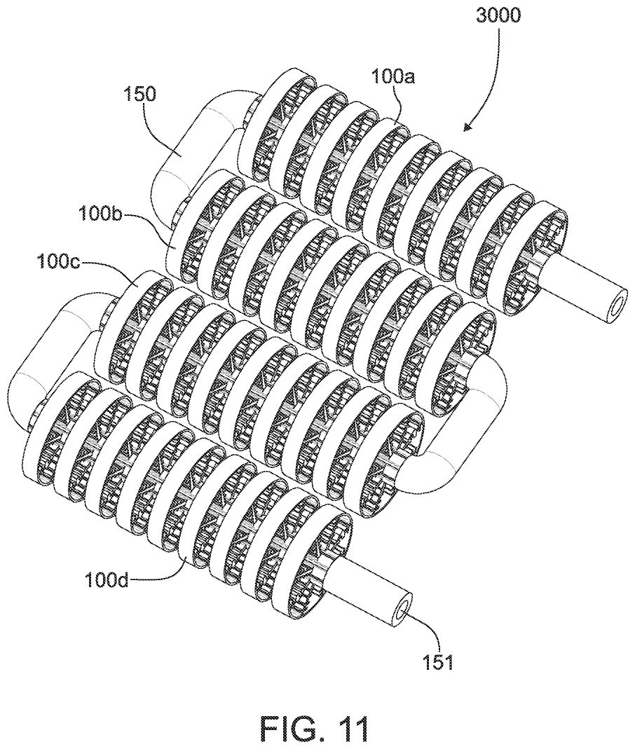

The embodiment shown in FIG. 1 illustrates an example with five openings dividing the profile 120 into five successive profile sections with a space between the first profile section and the coupler 150. FIGS. 2 and 3 show a minor modification of the construction of FIG. 1 with four openings dividing the profile 120 into four successive profile sections with a space between the first profile section and the coupler 150. The openings 140 in both examples have an equal axial coverage and distance from one another along the dimension of elongation of the heat sink 100. The embodiment of FIG. 4 shows a modified example with 14 openings 141 . . . 1414 dividing the profile 120 into respective 14 profile sections 121 . . . 1214. The heat sink 100 of FIG. 4 is shown “upside down” for illustrative purposes. The heat sink 100 is intended to be installed with the heat source at the bottom. The heat sink 100 may extend vertically or in a tilted orientation. The axial coverage of the openings of FIG. 4 vary such that axial coverage of each successive opening 141 . . . 1414 from the proximal end towards the distal end of the heat sink 100 is decreased leading to an increased axial height of the profile sections 121 . . . 1214. Accordingly, the distance between each successive opening may stay equal or decrease from the proximal end towards the distal end. The rest of the FIGURES illustrate further modification with FIG. 6 proposing three openings dividing the profile 120 into four profile sections, FIGS. 8 and 10 proposing four openings dividing the profile 120 into four profile sections, and FIG. 11 proposing 10 openings dividing the profile 120 into nine profile sections.

By varying the size and distribution of the openings 140, i.e. the relationship between the closed and opened parts of the profile 120, the chimney effect of the cooling air flow may be adjusted. Additionally, the air flow may be further promoted by providing the heat sink with a fan or comparable active flow device for promoting moving air from the intermediate volume to the ambient or vice versa (not illustrated in the FIGURES). In the example of FIG. 4, the first opening 141 at the proximal end near the heat source is relatively large compared to the fourteenth 1414 opening at the distal end furthest from the heat source. By decreasing the opening size along the dimension of elongation from the proximal to the distal end, the ambient air may enter the intermediate volume freely near the heat source, whereas towards the distal end the chimney effect will draw air in even from a relatively narrow opening. The openings between said first and last opening may change size gradually, linearly, or progressively.

Let us next consider the bridge 130. The bride 130 provides for a mechanical connection between the core 110 and the profile 120. The bridge 130 may be an integral component, meaning that the core 110, the profile 120, and the bridge 130 are constructed as one piece which cannot be disassembled in a non-destructive way. The bridge 130 extends from the core 110 in a generally radial fashion in respect to the dimension of elongation of the core 110. The illustrated embodiments show the bridge 130 being omitted from the sections of the heat sink 100 that are affected by the openings 140. As mentioned above, the bridge 130 may be left unremoved fully or partly at the openings (not shown in the FIGURES). Because the bridge 130 occupies the intermediate volume 160 between the core 110 and the profile 120, it is advantageous that the bridge 130 is not a solid piece but made up from several smaller elements that facilitate air flow in the intermediate volume 160 as well as between the intermediate volume 160 and the ambient for effective cooling.

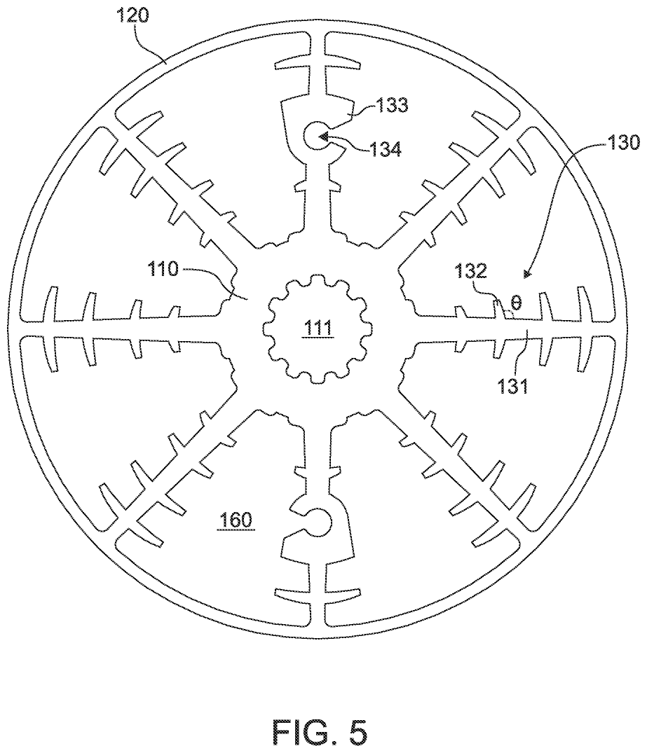

FIGS. 2 to 3 show one example of a bridge 130 involving a series of radial spokes 131 extending between the core 110 and the profile 120. The illustrated example includes six straight spokes 131 spread evenly around the core 110. FIGS. 1, 4, and 5 show a modified version of the simple straight spokes of FIGS. 2 and 3. As is best shown in FIG. 5, the surface area of the spokes 131 may be increased by adding fins 132. The fins 132 extend from the spokes 131 in a generally transverse orientation. Fins 132 may be provided on both sides of the spokes 131 or only on one side. The length of each successive fin 132 may increase from the core end towards the profile end so as to facilitate manufacturing. As a rule of thumb, the length and mutual distance of the fins 132 should be maximized to allow for a free flow of air in the intermediate volume 160. In practice, however, production of the heat sink by extrusion and machining will introduce limitations to the dimensions of the fins 132. The extrusion tools, for example, may have restrictions, such as a maximum tongue ratio or preferred geometrics of the extrusion tool for providing optimized flowing characteristics of the extrusion material. On the other hand, overly long fins may invoke vibrations during lathing.

As will later transpire, the openings 140 may be produced with a chip removing manufacturing technique. As the cutting tool is driven radially towards the core 110 cutting through the bridge 130, the cutting edge will move along the spoke 131, whereby the fin 132 may act as the end point or cutting depth for machining. To promote detachment of the chip from the bridge 130, the angle θ between the spoke 131 and the fin 132 is constructed to be more than 90 degrees for creating a guiding surface for the cutting edge. The outer surface of the fin 132 may be shaped to include a slight curve towards the core 110 for “dropping off” and thus aiding with ending the machining process. More specifically, the tangent of the fin 132 changes as a function of distance from the spoke 131. In other words, the angle of attack between the cutting tool and the fin 132 is decreased as a function of distance from the spoke 131. With the cutting edge making contact with the fin 132 in a slightly relieved angle, burring may be minimized or even eliminated. If the opening extends through the bridge 130, the core 110 may include a similarly shaped surface for ending the machining. More specifically, as shown in FIG. 5, the stem of the spoke 131 at the core 110 may include a similar burring-prevention shape as the fin 132.

Alternatively or additionally with an enlarged section to act as a socket 133 for acting as a mounting point for a component, such as a heat source, coupler, a controller, adjustment joint, etc. Additional or alternative mounting points may be provided to the profile 120, bridge 130, or core 110 during the additive manufacturing stage of the heat sink 100 by introducing a hole or screw pocket through the heat sink 120 along the dimension of elongation or subsequently by machining after the additive manufacturing step. The socket 133 may include a hole 134 preferably machined to include a female thread to facilitate a screw joint. Naturally, also other means of attachment are foreseeable, such as rivets, use of adhesives, etc. The hole 134 may be further utilized for running a power and/or control cable in the socket 133 between the proximal and distal end. FIG. 5 also reveals how the surface of the heat pipe 111 may be undulated to promote return flow of the fluid contained in the heat pipe 111. Particularly in a tilted installation it is advantageous that the heat pipe 111 includes splines or other longitudinally extending grooves for distributing the returning liquid around periphery of the heat pipe 111. A benefit of such undulations is that the returning fluid may flows on the bottom of the groove due to liquid dynamics somewhat isolated from the vapor surging in the opposite direction. Without such undulations all of the returning liquid would gather to flow along the lowest part of the heat pipe in the gravitation field and therefore collecting on a small area on the boiling surface of the coupler 150. Additionally or alternatively, the heat pipe effect may be further enhanced with introduction of a copper rod or comparable element into the internal channel of the core 110.

FIG. 6 shows a modification of the embodiment of FIGS. 2 and 3. Firstly, the core 110 is solid, i.e. it does not feature a channel. The heat source may be attached to the end or side of the core 110. Secondly, the spokes 131 are curved. The curvature is provided about axes which extend parallel to the dimension of elongation of the heat sink 100 adjacent to each spoke 131. The curvature creates a component of extension orthogonal to the lathing direction of the heat sink 100, which is beneficial during production of the openings. The curvature may decrease the risk of invoking resonance during lathing, when the heat sink is turned in the correct direction. The shape of the spokes may alternatively be varied to include shapes other than straight or curved, such as a shape resembling the letter S or Z.

Alternatively, the core may include a channel, into which an insert of a highly conducting material, such as copper, is inserted. The insert may be solid or hollow to include, e.g. a heat pipe.

The exemplary heat sinks 100 shown in FIGS. 1 to 6 all have the core 110 centred in respect to the profile 120. The core could, alternatively, be off-center in respect to the profile (not illustrated in the FIGURES). Accordingly, the bridge may be eccentric as well to accommodate such asymmetry.

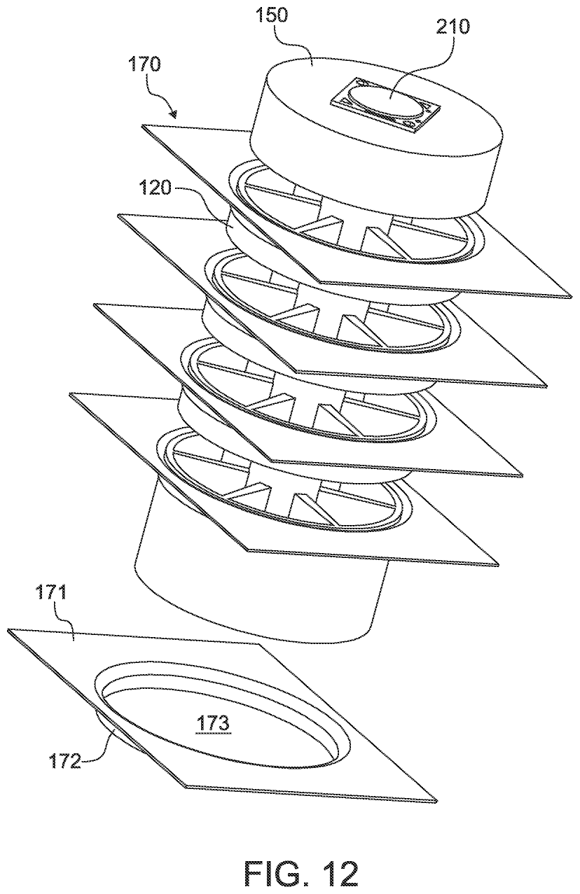

In addition to varying the size and arrangement of the openings and fins, additional components may be added to the heat sink to further promote heat dissipation. FIG. 12 proposes additional expander plates 170 which may be added to the profile 120, more particularly to one or more of the profile sections. FIG. 12 shows one of such expander plates 170 detached from the heat sink 100. As may be seen, the expander plate 170 may include a simple sheet 171 of metal, such as aluminium, aluminium alloy, steel or tin for example, with an opening 173 for receiving the profile 120, and a collar 172 extending from the sheet 171, defining the opening 173 and attaching to the profile 120. The collar 172 may be attached to the profile 120 through a heat transfer promoting agent, such as an adhesive, solder, heat paste, there between. Suitable joining methods therefore include gluing, soldering, welding, shrink fitting, etc. The introduction of such expansion plates 170 greatly increases the dissipating surface area of the profile 120 for promoting heat dissipation.

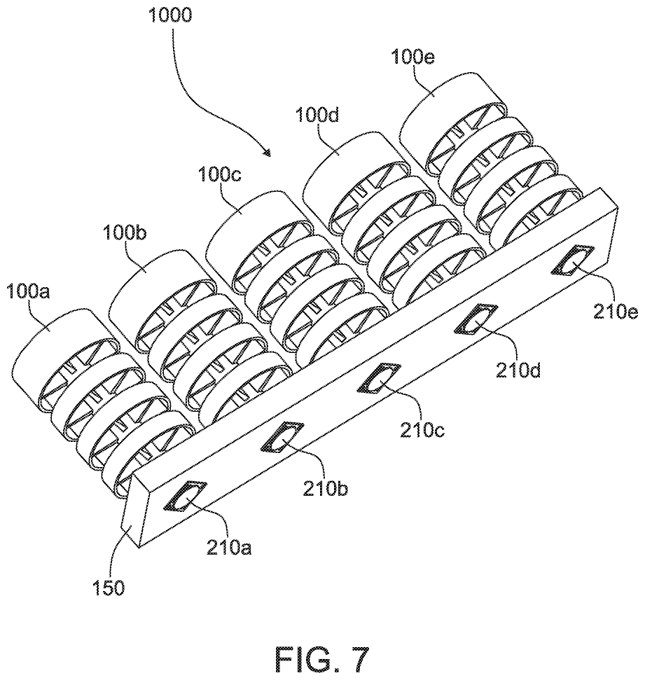

As established above, the novel heat sink concept may be varied to gain various advantages. FIGS. 7 to 11 and 13 to 15 show several practical applications and further variants of the heat sink concept.

FIGS. 7 and 8 shows a practical application of the heat sink concept as a variant of the embodiment of FIGS. 2 and 3. FIGS. 7 and 8 depict an illuminating system 1000 with a heat sources having five LED chips 210a, 210b, 210c, 210d, 210e and respective five associated heat sinks 100a, 100b, 100c, 100d, 100e all mounted on a shared coupler 150. The elongated coupler 150 therefore contains five spaced apart channels and vapour chambers 152 to connect the respective heat generating elements and the heat sinks into a heat transferring connection. The heat sinks 100a . . . 100e are mounted in a generally right angle in respect to the coupler 150. Naturally, the number and arrangement of LED chips 210a . . . 210e can be varied, for example by arranging the LED chips 210a . . . 210e into matrix, increasing or decreasing the number of LED chips 210a . . . 210e, and/or shaping the coupler into a non-straight form, e.g. into a two or three dimensional curve.

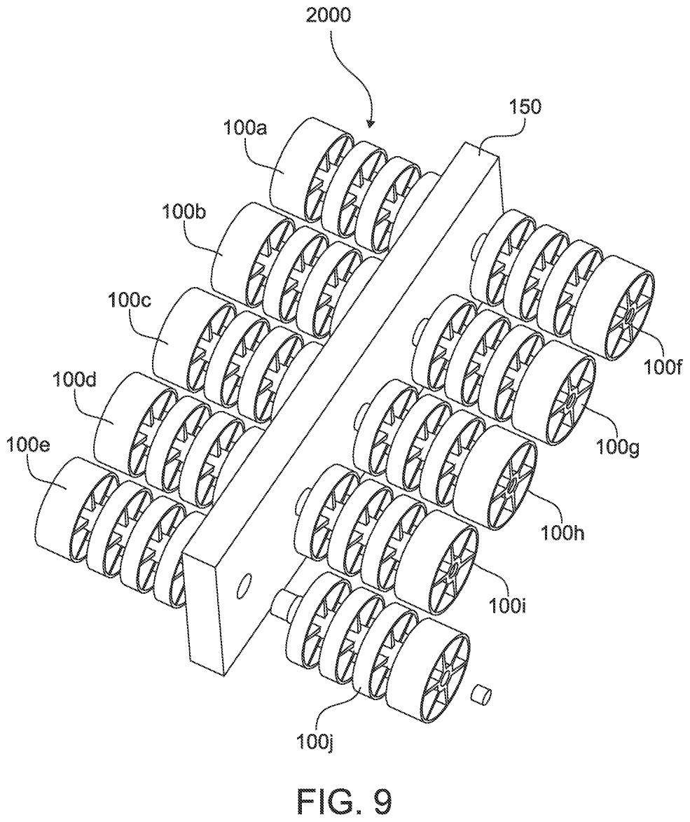

FIGS. 9 and 10 show another practical application of the heat sink concept as a variant of the embodiment of FIGS. 2 and 3. FIGS. 9 and 10 depict a heat exchanger 2000 with a shared, elongated coupler 150 similar to the embodiment of FIGS. 7 and 8 but with heat sinks provided on both sides of the coupler 150. Accordingly, the heat exchanger 2000 features a first heat sink set of five 100a . . . 100e arranged on one side of the coupler 150 and a second heat sink set of five 100f . . . 100j arranged on the opposing side of the coupler 150. The opposing heat sinks 100a, 100f, 100b, 100g; 100c, 100h; 100d, 100i; 100e, 100j are aligned with one another. Additionally, the channels 151 on the coupler 150 for the cores 110 of the heat sinks 100 run through the coupler 150 so as to bring the internal channels, e.g. the heat pipes 111, of the paired heat sinks 100a, 100f, 100b, 100g; 100c, 100h; 100d, 100i; 100e, 100j into fluid communication with one another. Accordingly, heat originating from one side of the coupler 150 may be transferred to the other side of the coupler 150 through the heat transferring connection between the two sides with aid of the joined heat pipes 111. The coupler 150 may be shaped to isolate the two sides from each other so as to prevent cross-contamination between gases or liquids prevailing on opposing sides of the coupler 150. The coupler may 150 may, for example, be shaped to form part of a flow channel or a reaction container.

FIG. 11 shows yet another practical application of the present heat sink concept depicting a flow-through radiator 3000. The flow-through radiator 3000 includes four heat sinks 100a, 100b, 100c, 100c, 100d arranged in succession with their respective inner channels connected in series and in fluid communication with one another with couplers 150. The couplers 150 according to the proposed embodiment take the form of simple pipes which may be straight at the inlet and outlet of the first and last heat sink 100a, 100d in the series, respectively, and or bent for connecting the outlet of a preceding heat sink to the inlet of the successive heat sink so as to form a compact meandering radiator. As mentioned above, the heat sink 100 is a variant of that shown in FIG. 4 with nine profile sections and a fully exposed core at both ends so as to act as inlets and outlets. Alternatively, the heat sinks 100a, 100b, 100c, 100c, 100d could be arranged in a straight or otherwise shaped configuration and/or with fewer or more heat sinks included in the radiator 3000. FIG. 11 shows the heat sinks connected in series but a parallel configuration is also foreseeable. Alternatively, the configuration may include several heat sink units arranged in series with different units including one or more than one heat sink connected in parallel. The radiator 3000 could be put into practice by feeding coolant through the heat sinks 100a, 100b, 100c, 100c, 100d for dissipating heat contained in the coolant to the ambient by means of the inner channel and associated air flow enhanced bridge 130 and profile 120.

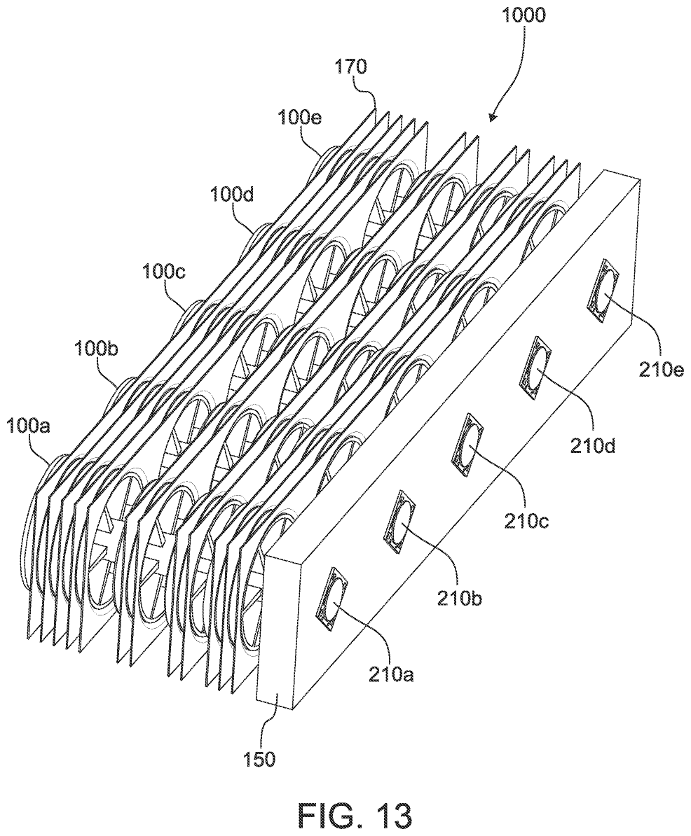

FIG. 13 shows a combination of the embodiments of FIG. 7 featuring five LED chips 210a . . . 210e and respective five associated heat sinks 100a . . . 100e mounted on a shared coupler 150 equipped with expander plates 170 shown in FIG. 12. In the embodiment of FIG. 13 each profile section carries more than one expander plate 170. As a variant of FIG. 12, the expander plates 170 elongated and provided with five mutually parallel openings to accommodate the respective five parallel profiles 120.

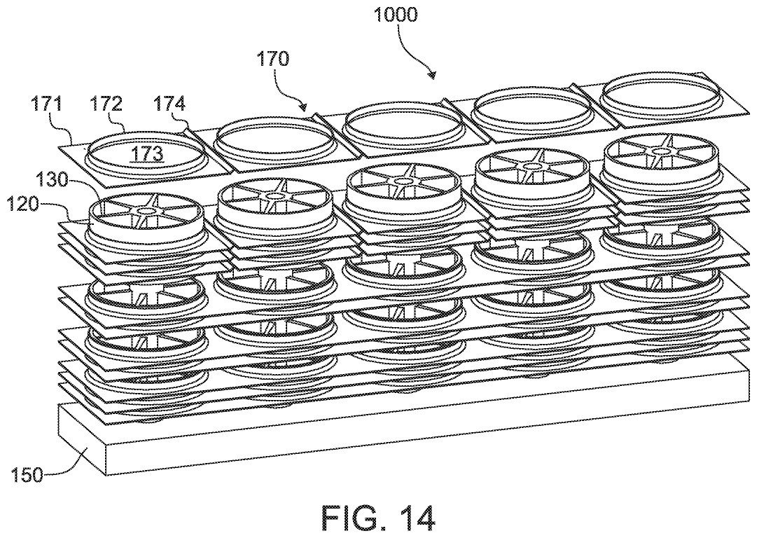

FIG. 14 shows a variant of the expander plates 170 shown in FIG. 13. The expander plates 170 of FIG. 14 include creases 174 between each parallel opening 172 on the sheet 171. The creases 174 increase flexibility of the expander plate 170 for aiding installation and alignment with the profiles 120. The creases 174 form an axis of elastic deformation about which the expander plate 170 may be bent relatively easily.

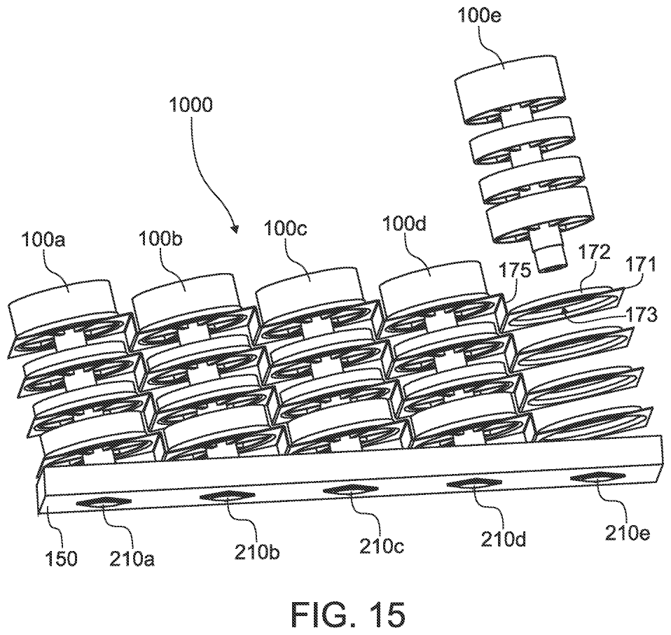

FIG. 15 shows yet another variation of the illuminating system 1000 shown in FIGS. 7, 13, and 14. Firstly, the expander plates 170 have been provided with folds 175 between each parallel opening 172 on the sheet 171. The folds 175 introduce a plane shift between successive openings 172 in the expander plate 170. The reason for that is in the second major variation of the illuminating system 1000. According to the embodiment of FIG. 15, the heat sinks 100a . . . 100e are mounted in a slanted angle, i.e. in a non-straight angle, in respect to the elongated shared coupler 150. The purpose of the slanted mounting angle is to enable vertical installation of the coupler 150 (shown in horizontal in FIG. 15), whereby the fluid contained in the heat pipe will flow down towards the coupler 150. In other words, the tilted mounting angle of the heat sinks in respect to the coupler brings the cores in a non-aligned orientation in respect to the gravity field.

As briefly mentioned above, the present heat sink concept is particularly advantageous in terms of manufacturing with conventional manufacturing equipment. The manufacturing of the heat sink 100 has three major manufacturing steps with optional finishing steps. First, a preform is made with an additive manufacturing technique, such as extrusion, casting, 3D printing, injection molding, etc. The preform may be produced form a material which is suitable for such a manufacturing technique and has suitable heat conducting properties. Foreseeable raw materials include aluminum, copper, alloy or composite, etc. The preform includes the core 110, the outer profile 120, and the bridge 130 which are preferably provided for in the same additive manufacturing stage. Accordingly, these three major parts 110, 120, 130 are integral to each other.

With the first major manufacturing step completed, the openings 140 are provided to the pre-form in the second major manufacturing step. The openings 140 may be added with a chip removing manufacturing technique or another material removing technique. A preferred material removing technique is lathing. If, as shown, the profile 120 has a generally circular cross-sectional shape, it may be easily attached to the spindle jaws. According to a particular, the second manufacturing step is performed in a CNC lathe with a through spindle feed. Lathing is particularly advantageous for producing the radially extending openings 140 through the profile 120 and optionally through the bridge 130. If the openings are to extend in a direction which includes a component in the dimension of elongation of the heat sink, a multi-axis CNC machine may be the preferred option.

The two major manufacturing steps may be succeeded or preceded by a third stage which is a cutting stage for cutting the preform of heat sink into an appropriate length. The cutting may be performed with a conventional method, such as lathing, CNC machining, plasma cutting, laser cutting, water cutting etc.

The product may be finished by machining chamfers or other relieved edges to the heat sink and/or deburring, if necessary. Additionally, the material of the heat sink may be treated against corrosion or otherwise enhanced for presentation purposes.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the following description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, i.e. a singular form, throughout this document does not exclude a plurality.

### INDUSTRIAL APPLICABILITY

The present heat sink concept may be utilized as a heat dissipating solution for use in, e.g., an illuminator shown in FIGS. 1, 2, and 3, illuminating system 1000 shown in FIGS. 7, 8, 13, 14, and 15, heat exchanger 2000 shown in FIGS. 9 and 10, and radiator 3000 shown in FIG. 11. The shown concept could also be applied by providing one heat source, such as an IGBT module, with several heat sinks, e.g. by the setup shown in FIG. 7, wherein the flow channels would be connected in the coupler, on which the heat source is mounted.

REFERENCE SIGNS LIST

| No. | Feature | No. | Feature |
|---|---|---|---|
| 100 | heat sink | 152 | vapor chamber |
| 110 | core | 160 | intermediate volume |
| 111 | heat pipe | 170 | expander plate |
| 112 | shoulder | 171 | sheet |
| 113 | seat | 172 | collar |
| 114 | plug | 173 | opening |
| 120 | profile | 174 | crease |
| 121 | first profile section | 175 | fold |
| 122 | second profile section | 200 | heat source |
| 123 | third profile section | 210 | component, e.g. |
| | | | LED chip |
| 124 | fourth profile section | 220 | reflector |
| 1214 | fourteenth profile | 230 | body |
| | section | | |
| 130 | bridge | 1000 | illuminating system |
| 131 | spoke | 2000 | heat exchanger |
| 132 | fin | 3000 | flow through radiator |
| 133 | socket | CP1 . . . CP5 | center points |
| 134 | hole | DE | direction of extension |
| 140 | opening | E1 | first side edge |
| 141 | first opening | E2 | second side edge |
| 142 | second opening | E3 | first end edge |
| 143 | third opening | E4 | second end edge |
| 144 | fourth opening | P1.1 . . . P5.1 | first reference points |
| 1414 | fourteenth opening | P1.2 . . . P5.2 | second reference points |
| 150 | coupler | SL1 . . . SL5 | line segments |
| 151 | channel | | |

### CITATION LIST

US 2009071624 A1
EP 2193310 B1

1. A heat sink comprising:
an inner core elongated along a dimension of elongation;
an outer profile, which:
is provided along, around, and distanced from the core such that an intermediate volume is formed between the core and the profile, and
comprises at least one opening exposing the intermediate volume to the ambient, wherein the at least one opening extends in a direction, which is non-parallel to the dimension of elongation of the inner core, and
a bridge connecting the profile to the core.

2. The heat sink according to claim 1, wherein the at least one opening extends in a direction which has a component along the cross-sectional periphery of the profile.

3. The heat sink according to claim 1, wherein the at least one opening extends along the periphery of the profile.

4. The heat sink according to claim 1, wherein the at least one opening extends around the entire periphery of the profile splitting the profile into several profile sections.

5. The heat sink according to claim 1, wherein the profile is elongated in a dimension of elongation and comprises a plurality of said openings spaced apart from each other along the profile in the dimension of elongation of the profile.

6. The heat sink according to claim 5, wherein the openings are provided radially in respect to and rotationally about the dimension of elongation of the core.

7. The heat sink according to claim 1, wherein the at least one opening extends through the bridge exposing the core to the ambient.

8. The heat sink according to claim 1, wherein the core is hollow.

9. The heat sink according to claim 1, wherein the core comprises a heat pipe.

10. The heat sink according to claim 9, wherein the heat pipe is integrated into the core.

11. The heat sink according to claim 9, wherein the heat pipe is closed and comprises a phase transition fluid for performing a thermosiphon cycle.

12. The heat sink according to claim 1, wherein the bridge comprises a plurality of spokes extending between the core and the profile through the intermediate volume.

13. The heat sink according to claim 12, wherein at least one spoke comprises a plurality fins extending from the at least one spoke.

14. The heat sink according to claim 13, wherein:
an initial extending angle of more than 90 degrees is formed between the spoke and the fin on the profile side of the fin,
the tangent of the fin changes as a function of distance from the spoke increasing the angle formed between the spoke and the tangent of the fin on the profile side of the fin, or wherein
an initial extending angle of more than 90 degrees is formed between the spoke and the fin on the profile side of the fin and the tangent of the fin changes as a function of distance from the spoke increasing the angle formed between the spoke and the tangent of the fin on the profile side of the fin.

15. The heat sink according to claim 12, wherein at least one spoke comprises a socket for acting as a mounting point.

16. The heat sink according to claim 1, wherein the heat sink comprises a coupler for receiving a heat source.

17. The heat sink according to claim 16, wherein the coupler comprises a channel for receiving the core and a vapour chamber in fluid communication with the channel.

18. The heat sink according to claim 17, wherein the cross-section of the vapour chamber is larger than that of the channel.

19. The heat sink according to claim 1, wherein the parts making up the heat sink are integral to one another.

20. A heat dissipating system, comprising:
a plurality of heat sinks, each of which comprises:
an inner core elongated along a dimension of elongation;
an outer profile, which is provided along, around, and distanced from the core such that an intermediate volume is formed between the core and the profile, and which outer profile comprises at least one opening exposing the intermediate volume to the ambient, wherein the at least one opening extends in a direction, which is non-parallel to the dimension of elongation of the inner core; and
a bridge connecting the profile to the core, and
a coupler for receiving a heat source, wherein the coupler comprises:
a plurality of said-channels for receiving the cores of the plurality of heat sinks into fluid communication with each other.

21. An illuminator comprising:
a heat sink comprising:
inner core elongated along a dimension of elongation;
outer profile, which is provided along, around, and distanced from the core such that an intermediate volume is formed between the core and the profile, and which outer profile comprises at least one opening exposing the intermediate volume to the ambient, wherein the at least one opening extends in a direction, which is non-parallel to the dimension of elongation of the inner core;
a bridge connecting the profile to the core, and
a coupler for receiving a heat source, and
an artificial light source mounted on the coupler.

22. An illuminating system comprising:
a plurality of illuminators each comprising artificial light source;
a plurality of heat sinks, each of which comprising:
an inner core elongated along a dimension of elongation;
an outer profile, which is provided along, around, and distanced from the core such that an intermediate volume is formed between the core and the profile, and which outer profile comprises at least one opening exposing the intermediate volume to the ambient, wherein the at least one opening extends in a direction, which is non-parallel to the dimension of elongation of the inner core; and
a bridge connecting the profile to the core, and
a shared coupler comprising a plurality of channels for receiving the cores of the plurality of heat sinks,
wherein the plurality of artificial light sources are mounted on the shared coupler.

23. A method for producing a heat sink comprising:
providing a pre-form with an additive manufacturing technique to include:
an inner core;
an outer profile, which forms a periphery and is provided around and at a distance from the core such that an intermediate volume is formed between the core and the profile, and
a bridge connecting the profile, and
providing at least one opening to the profile with a material removing manufacturing technique such that the at least one opening extends in a direction which has a component along the periphery of the profile and exposes the intermediate volume to the ambient.

24. (canceled)

25. The method according to claim 23, wherein the additive manufacturing technique is extrusion.

26. The method according to claim 23, wherein the material removing manufacturing technique is a chip removing manufacturing technique, such as lathing.

27. A method of installing a heat source to a receptive structure-comprising:
providing a heat sink, which comprises:
an inner core elongated along a dimension of elongation;
an outer profile, which is provided along, around, and distanced from the core such that an intermediate volume is formed between the core and the profile, and which outer profile comprises at least one opening exposing the intermediate volume to the ambient, wherein the at least one opening extends in a direction, which is non-parallel to the dimension of elongation of the inner core, and
a bridge connecting the profile to the core,
mounting the heat source on the heat sink, and
installing elongated heat sink in a non-horizontal tilted angle in respect to the vertical with the heat source facing down.

28. A heat exchanger comprising:
a first heat sink, which comprises:
an inner hollow core elongated along a dimension of elongation;
an outer profile, which is provided along, around, and distanced from the core such that an intermediate volume is formed between the core and the profile, and which outer profile comprises at least one opening exposing the intermediate volume to the ambient, wherein the at least one opening extends in a direction, which is non-parallel to the dimension of elongation of the inner core, and
a bridge connecting the profile to the core,
a second heat sink, which comprises:
an inner hollow core elongated along a dimension of elongation;
an outer profile, which is provided along, around, and distanced from the core such that an intermediate volume is formed between the core and the profile, and which outer profile comprises at least one opening exposing the intermediate volume to the ambient, wherein the at least one opening extends in a direction, which is non-parallel to the dimension of elongation of the inner core, and
a bridge connecting the profile to the core, and
a coupler connecting the hollow cores of the first and second heat sink into a flowing connection with one another.

29. The heat exchanger according to claim 28, wherein the heat sinks and the coupler form a closed heat transferring channel.

30. The heat exchanger according to claim 28, wherein the heat exchanger comprises more than one such pair of heat sinks.

31. The heat exchanger according to claim 28, wherein the heat exchanger is a flow through heat exchanger, and wherein a coolant may flow through the heat sinks and coupler.

32. The heat exchanger according to claim 31, wherein the heat exchanger comprises more than one such coupler connecting more than two such heat sinks in succession.
